(19) United States
(12) Patent Application Publication
(10) Pub. No.: US 2006/0255479 A1
(43) Pub. Date: Nov. 16, 2006

(54) Magnetic assist manufacturing to reduce mold flash and assist with heat slug assembly

(75) Inventors: Steven Alfred Kummerl, Carrollton, TX (US); Bemhard Peter Lange, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/125,712

(22) Filed: May 10, 2005

(51) Int. Cl. H01L 23/28

(52) U.S. Cl. 257/787

(57) ABSTRACT

A method (300) and apparatus (200) for fabricating a semiconductor package (100), wherein a heat spreader (118) is placed in a mold cavity (204) of a mold (202), and a leadframe (108) is placed over the heat spreader (118). A magnetic field (218) is applied to the mold cavity (204), wherein one or more of the heat spreader (118) and leadframe (108) are generally attracted to a surface (212) of the mold cavity (204), thus generally determining a position (214) of the heat spreader (118) within the mold cavity (204) and defining a contact region (120) between the heat spreader (118) and the mold (202). An encapsulation material (114) is further injected into the mold cavity (204), wherein the encapsulation material (114) is generally prevented from entering the contact region (120) due, at least in part, to the applied magnetic field (218). The encapsulation material (114) is then cured, and the semiconductor package (100) is removed from the mold cavity (204).

### FIELD OF THE INVENTION

The present invention relates generally to semiconductor devices and processes, and more particularly to a system and method for assembling a semiconductor package with a heat spreader having reduced mold flash.

### BACKGROUND OF THE INVENTION

In the semiconductor industry, integrated circuit (IC) speeds and densities are continuously increasing, and the need for improved thermal performance (i.e., improved dissipation of heat) has become more and more important. FIG. 1, for example, illustrates a conventional semiconductor package 10 that utilizes a leadframe 15 as a carrier for an integrated circuit or chip 20 (e.g., a semiconductor die). The chip 20 is mounted on a die pad 25 of the leadframe 15 and electrically coupled thereto by bond wires 30 that are used to electrically connect leads 35 of the leadframe to selected bond pads (not shown) on the chip. The chip is further encapsulated by a plastic or resin 40 in a molding process. Thus, the plastic or resin 40 generally defines an encapsulation body 45, wherein the leads 35 of the leadframe 15 are partially exposed to the outside of the encapsulation body for electrically coupling to an external printed circuit board (not shown). One drawback to this type of semiconductor package structure, however, is that since the entire chip 20 and the die pad 25 are generally encapsulated within the encapsulation body 45, heat dissipation from the area about the chip is considerably low.

One conventional solution to the heat dissipation problem is to include a heat spreader (also called a heat sink or heat slug) in the semiconductor package, wherein the heat spreader helps to increase the heat dissipation efficiency of the semiconductor package. FIG. 2 illustrates a typical semiconductor package 50 comprising a heat spreader 55, wherein the heat spreader is intended to contact the die pad 25 in order to assist in dissipating heat from the die pad and chip 20. FIG. 3 illustrates a cross-sectional view of a conventional two-part mold 60 for forming the typical semiconductor package 50 of FIG. 2, wherein the heat spreader 55, leadframe 15, and a chip 20 are disposed within a cavity 65 of the mold 60 prior to encapsulation. Typically, the heat spreader 55 is “dropped in” to the mold cavity 65 so that a bottom portion 70 of the heat spreader contacts a mold contact surface 75 of the mold 60. In a previous operation, for example, the chip 20 is attached to the die pad 25 of the leadframe 15, and the bond wires 30 are connected between the leads 35 of the leadframe and selected bond pads (not shown) on the chip. The leadframe 15, chip 20 and bond wires 30 are placed in the mold cavity 65, such that a bottom pad surface 80 of the die pad 25 is intended to contact a top surface 85 of the heat spreader 55. Two mold halves 90A and 90B of the mold 60 are then closed together, and encapsulation material (not shown) is transferred into the mold cavity 65 until the cavity is full. When the encapsulation material solidifies, the mold 60 is opened and the completed package removed.

One further improvement to try to resolve the problem of heat dissipation from integrated circuit packages, such as the package 50 of FIG. 2 has been an attempt to expose the bottom portion 70 of the heat spreader 55 directly to the exterior of the package 50, such that an external heat sink (not shown) can be thermally coupled to the heat spreader, thereby greatly reducing the thermal resistance attributable to the presence of the plastic encapsulation. All of the above attempts at resolving the heat dissipation problem, however, have had mixed success when used with the “drop in” technique described above, due to various manufacturing difficulties. For example, high pressures and turbulence present within the mold cavity 65 of FIG. 3 during the encapsulation process can move the heat spreader 55 within the cavity, thus yielding sub-optimal contact between surfaces, thus leading to decreased thermal efficiencies, or even varying thermal efficiencies from piece to piece.

Furthermore, characteristics of the encapsulation material (e.g., viscosity) and dimensional variations from piece to piece between particular heat spreaders 55 have also combined to produce a separation between the surfaces of the heat spreader and the mold contact surface 75 of the mold 60 and bottom pad surface 80 of the die pad 25 during encapsulation, thus further deleteriously affecting thermal efficiencies. Inadequate sealing between the bottom pad surface 80, the mold contact surface 75, and the heat spreader 55, for example, generally allows encapsulation material to flow or bleed between the heat spreader, die pad 25, and mold 60, thus forming flash 95 (the undesirable presence of encapsulation material) on the heat spreader surface(s), as illustrated in FIG. 2, thus deleteriously impacting the thermal performance of the semiconductor package 50. Bleed and flash 95 are typically undesirable both because they degrade the heat transfer capability of the heat spreader 55 to conduct heat from the chip 20 and because they are unsightly cosmetic defects that customers typically find undesirable in the finished product. This unwanted plastic necessitates extensive and expensive cleaning and post-processing of the exposed heat spreader surface prior to subsequent processing operations.

Therefore, a need currently exists for a reliable process for manufacturing semiconductor packages having heat spreaders, wherein thermal performance is substantially improved, and wherein post-processing of the heat spreader to remove bleed or flash is substantially minimized.

### SUMMARY OF THE INVENTION

The present invention overcomes the limitations of the prior art by providing an improved molding apparatus and method for forming an integrated circuit or semiconductor package, wherein a magnetic field associated with the molding apparatus is utilized determine a position of one or more magnetically susceptible components of the integrated circuit package. Accordingly, the following presents a simplified summary of the invention in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

The present invention is generally directed toward an improved method and apparatus for fabricating a integrated circuit package. More particularly, the invention is directed toward the utilization of a magnetic field associated with the molding apparatus to control a position or orientation of one or more of a heat spreader and leadframe associated with the semiconductor package. In accordance with one exemplary aspect of the present invention, the molding apparatus comprises a first mold half and a second mold half, wherein one of the first and second mold halves comprises a magnet embedded therein. The magnet is operable to generally attract one or more magnetically susceptible components of the semiconductor package, such as one or more of a heat spreader and a leadframe, to a surface of a cavity defined by the two mold halves, wherein a position of the one or more components is generally controlled by the magnetic field.

The magnet, for example, may comprise a permanent magnet or an electromagnet, wherein the magnet is operable to generally attract one or more paramagnetic materials associated with the one or more components. In one example, the one or more magnetically susceptible components comprise a paramagnetic coating formed thereon, wherein the magnet is operable to generally attract the one or more components by attracting the paramagnetic coating to the surface of the cavity. By attracting the heat spreader to the surface of the cavity, for example, the magnet is operable to generally seal a bottom portion of the heat spreader, such that upon an injection of a molding or encapsulation compound into the cavity, the bottom portion of the heat spreader is not substantially exposed to the encapsulation compound. Such an unexposed bottom portion of the heat spreader generally increases a thermal efficiency of the resulting semiconductor package Furthermore, in accordance with another example, mating surfaces between the leadframe and the heat spreader are substantially compressed against one another by the magnetic field, wherein a further seal between the leadframe and heat spreader may be achieved in order to further increase the thermal efficiency of the semiconductor package.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 illustrates a cross-sectional view of a conventional integrated circuit package.

FIG. 2 illustrates a cross-sectional view of a conventional integrated circuit package with a heat spreader incorporated therein.

FIG. 3 illustrates a cross-sectional view of a conventional mold for forming an integrated circuit package with a heat spreader incorporated therein.

FIG. 4 illustrates a cross-sectional view of an exemplary IC package in accordance with one aspect of the present invention.

FIG. 5 illustrates a cross-sectional view of an exemplary mold apparatus in a closed position in accordance with one aspect of the present invention.

FIG. 6 illustrates a cross-sectional view of an exemplary mold apparatus in an open position in accordance with one aspect of the present invention.

FIG. 7 is a block diagram schematic of an exemplary method for fabricating an integrated circuit package in accordance with the present invention.

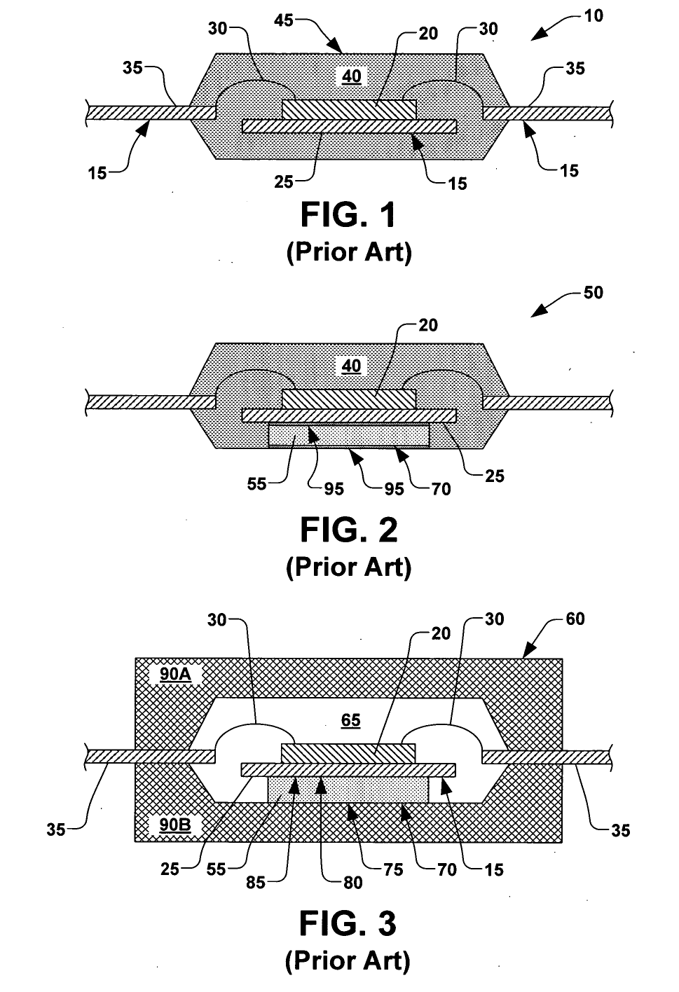

### DETAILED DESCRIPTION OF THE INVENTION

The present invention is directed towards a molding apparatus and method for fabricating an integrated circuit (IC) package comprising an encapsulated chip and a heat spreader. More particularly, the present invention provides a robust process for substantially improving a thermal conduction efficiency of the semiconductor package by limiting an amount of bleed or flash of encapsulation material associated with surfaces of the heat spreader, while also positioning the heat spreader in a uniform and repeatable manner. Accordingly, the present invention will now be described with reference to the drawings, wherein like reference numerals are used to refer to like elements throughout. It should be understood that the description of these aspects are merely illustrative and that they should not be taken in a limiting sense. In the following description, for purposes of explanation, numerous specific details are set forth in order to provide a thorough understanding of the present invention. It will be evident to one skilled in the art, however, that the present invention may be practiced without these specific details.

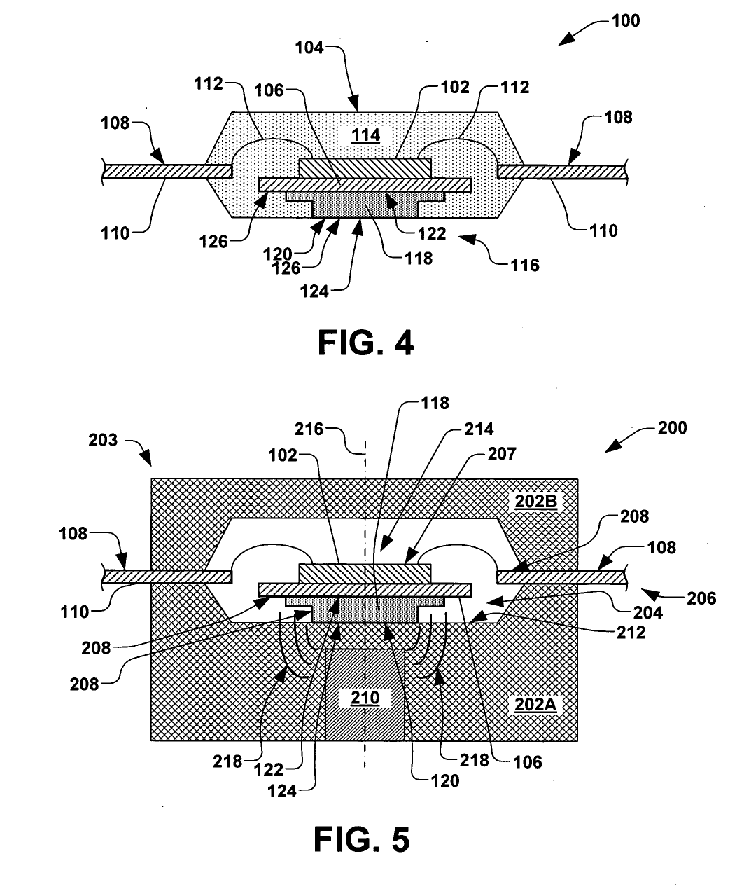

Referring now to the figures, FIG. 4 illustrates a cross-sectional view of an exemplary IC package 100 that is formed by the present invention, as will be discussed hereafter. The IC package 100, for example, comprises a semiconductor die or chip 102 that is disposed within an encapsulation body 104 on a die pad 106 of a leadframe 108. The chip 102 is electrically connected to a plurality of leads 110 of the leadframe 108 via a plurality of bonding wires 112. It should be noted that the die pad 106 and plurality of leads 110 of the leadframe 108 are coupled to one another (e.g., by tie bars), however, such coupling is not illustrated in FIG. 4 for purposes of clarity. The chip 102 of the IC package 100 is further encapsulated within the encapsulation body 104 by an encapsulation compound or material 114, such as an epoxy or plastic resin, wherein the chip is substantially isolated (e.g., electrically and environmentally isolated) from an external environment 116, except for the plurality of leads 110 that are electrically coupled to the chip. In accordance with the present invention, the IC package 100 further comprises a heat spreader 118 (e.g., a heat slug) positioned within the encapsulation body 104, wherein the heat spreader is operable to efficiently transfer heat from the chip 102 and die pad 106 to a region 120 that is generally distant from the chip and die pad.

In one example, the heat spreader 118 is thermally coupled to the die pad 104 at a first interface 122 between the heat spreader and the die pad. As will be discussed infra, a bottom surface 124 of the heat spreader 118 is further exposed to the external environment 116, wherein the bottom surface of the heat spreader has virtually no encapsulation material 114 disposed thereon after molding. Thus, a highly efficient transfer of thermal energy from the chip 102 to the external environment 116 can be attained, thus improving the reliability of the IC package 100. In accordance with the present invention, one or more of the heat spreader 118 and leadframe 108 are either comprised of, or coated with, a material 126 that is generally susceptible to a magnetic field, such as a paramagnetic material, one purpose of which will be described hereafter. The material 126 need not be highly magnetic in nature, but should be relatively magnetic when compared to the chip 102 and encapsulation material 114. Exemplary paramagnetic materials may comprise nickel or an alloy of nickel, such an alloy of nickel, palladium, and gold. It should also be noted that the heat spreader 118 may be positioned elsewhere within the encapsulation body 104, such as in a position (not shown) above the chip 102, and that all such positions are contemplated as falling within the scope of the present invention.

Referring now to FIG. 5, a cross-sectional view of an exemplary molding apparatus 200 for forming the exemplary IC package 100 of FIG. 4 is illustrated. It should be noted that while the molding apparatus 200 of FIG. 5 is described hereafter with reference to the IC package 100 of FIG. 4, the molding apparatus is not limited to producing the IC package 100 of FIG. 4, and that various other configurations of IC packages may be alternatively formed using the molding apparatus 200 of FIG. 5. The molding apparatus 200, for example, comprises a separable first mold half 202A and second mold half 202B (e.g., a “clam shell” mold), wherein the mold apparatus is illustrated in a closed position 203, and wherein a mold cavity or chase 204 is generally defined between the first and second mold halves. The first mold half 202A and second mold half 202B, for example, are operable to separated from one another, as will be described in greater detail hereafter. FIG. 5 further illustrates the heat spreader 118, leadframe 108, and chip 102 disposed within the chase 204 prior to encapsulation, wherein the leads 110 of the leadframe generally extend from the chase to an external portion 206 of the molding apparatus 100. In the present example, the chip 102 has been previously coupled to the die pad 106 of the leadframe 108 and the chip 110 has been wire-bonded to the plurality of leads 110 in a previous process, thus defining a leadframe assembly 207.

As discussed above, in accordance with one exemplary aspect of the present invention, one or more of the heat spreader 118 and leadframe 108 comprise a material that is generally susceptible to a magnetic field. In a preferred embodiment, one or more of the heat spreader 106 and leadframe 108 comprise a paramagnetic coating 208 comprising an alloy made of nickel, palladium, and gold. Furthermore, the heat spreader 118 preferably comprises a material having a high thermal conductivity, such as copper or aluminum that is coated with the paramagnetic coating 208, such that the heat spreader generally maintains an advantageous high thermal conductivity, while further being susceptible to a magnetic field.

In accordance with the present invention, the mold apparatus 200 further comprises a magnet 210, such as an electromagnet or a permanent magnet, wherein the magnet is associated with the first mold half 202A or the second mold half 102B. For example, the magnet 210 is positioned within the first mold half 202A and beneath an internal surface 212 of the chase 204, and is generally associated with a desired position 214 of one or more of the heat spreader 118, leadframe 108, and chip 102 with respect to the chase. In one example, the magnet 210 is generally embedded in the first mold half 202A along a centerline 216 of the chase 204, wherein the magnet is operable to create a magnetic field 218 within the chase 204.

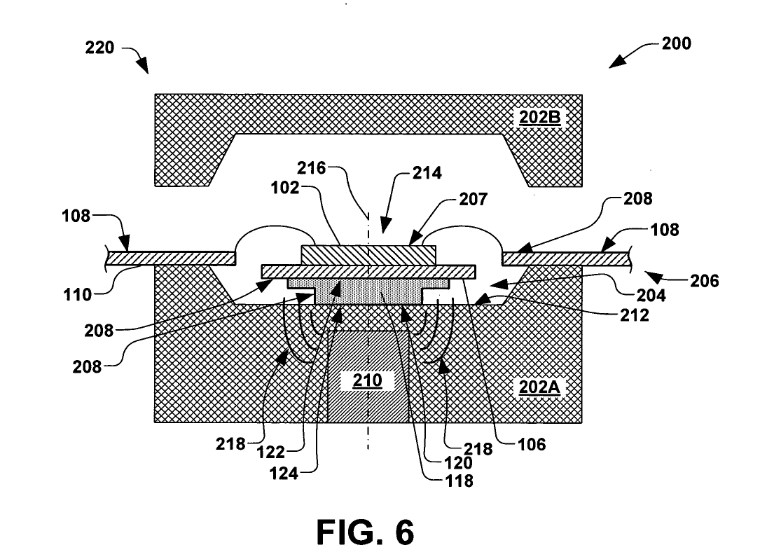

In the present example, in the process of forming an IC package, such as the IC package 100 of FIG. 4, the heat spreader 118 illustrated in FIG. 5 is generally placed or dropped in to the mold cavity or chase 104 of the first mold half 202A of the mold apparatus 200 when the mold apparatus is in an open position 220, as illustrated in FIG. 6, such that the bottom surface 124 of the heat spreader contacts the internal surface 212 of the chase 204. In a production environment, wherein a matrix (not shown) of mold apparatuses 200 are utilized to form a plurality of IC packages generally simultaneously, each heat spreader 118 may be dropped into the respective chase 204 individually, or alternatively, as a matrix array of heat spreaders that may be dropped into the corresponding matrix of chases generally simultaneously. The heat spreader 118 may also be dropped into the mold cavity or chase 204 by a coin-stack type dispenser.

According to the present invention, when the heat spreader 118 is dropped into the chase 204, the heat spreader it is operable to be aligned with respect to the chase by the magnetic field 218. In the case of the magnet 210 being a permanent magnet, the magnetic field is substantially constant, and the heat spreader 118 is automatically aligned within the chase 204 by the magnetic field. Alternatively, in the case of the magnet 210 being an electromagnet, the heat spreader 118 is aligned within the chase when the electromagnet is energized. As another alternative, the magnet 210 may be movable within the first mold half 202A, wherein the heat spreader 118 is aligned with the chase 204 when the magnet is moved near the chase 204. Therefore, one or more of the heat spreader 118 and leadframe 108 are operable to maintain a generally fixed position within the chase 104 while under the influence of the magnetic field 218 due, at least in part, to the paramagnetic coating 208.

Once the heat spreader 118 is placed in the chase 204, the leadframe assembly 207 is positioned over the chase. For example, the leadframe assembly 207 is mounted on the first mold half 102A by placing holes (not shown) in the leadframe 108 over pins (not shown) associated with the first mold half 202A. The magnetic field 218 further generally causes the die pad 106 (which comprises the paramagnetic coating 208) to be pulled toward the heat spreader 118, thus generally gasketing the die pad and the heat spreader 118 along the first interface 122, and further forcing the bottom surface 124 of the heat spreader against the internal surface 212 of the chase 204. Such a magnetic pull thus further holds the heat spreader 118 in place, and further results in a tight seal between the heat spreader and the internal surface 212 of the chase 204.

In accordance with another exemplary aspect of the invention, the first and second mold halves 202A and 202B are then placed in the closed position 203 illustrated in FIG. 5, wherein an encapsulation material or compound (not shown) is selectively transferred into the mold cavity or chase 204 through one or more channels or ports (not shown) from an encapsulation material source (not shown) until the cavity is full. Due to the tight seal between the bottom surface 124 of the heat spreader 118 and the internal surface 212 of the mold cavity 204, encapsulation material is generally prohibited from entering the region 120 along the bottom surface of the heat spreader, thus generally preventing bleed or flash from forming on the bottom surface of the heat spreader when the encapsulation material solidifies. When the encapsulation material solidifies, the mold apparatus 200 is again opened by separating the first and second mold halves 202A and 202B, and the IC package 100 of FIG. 4 is removed therefrom. Accordingly, the bottom surface 124 of the heat spreader 118 of the finished IC package 100 thus provides a high thermal conductance efficiency from the heat spreader to an external component, such as a heat sink (not shown).

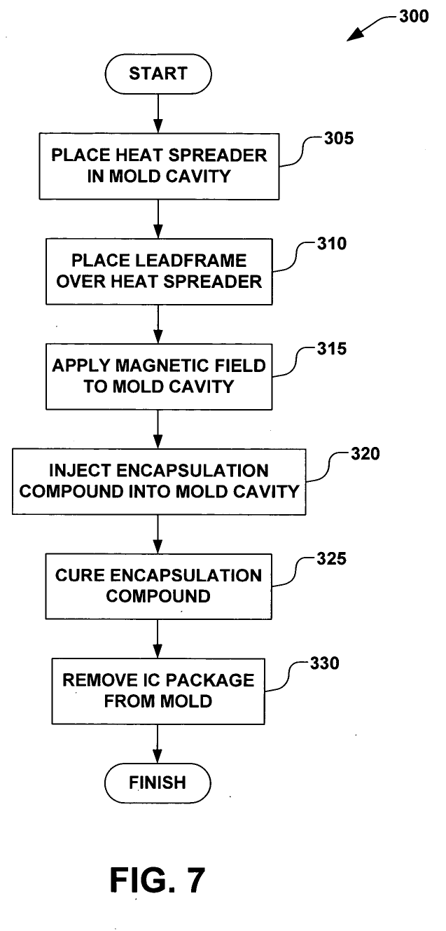

According to another aspect of the present invention, FIG. 7 is a block diagram illustrating an exemplary method 300 for fabricating an IC package. While exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

As illustrated in FIG. 7, the method 300 begins with act 305, wherein a heat spreader is placed in a mold cavity of a mold apparatus. The mold apparatus, for example, is similar to the mold apparatus 200 of FIGS. 5 and 6, wherein the mold apparatus has a magnet 210 associated therewith. In act 310 of FIG. 7, a leadframe is placed over the heat spreader, and a magnetic field is applied to the mold cavity in act 315. One or more of the heat spreader and leadframe are further generally susceptible to the magnetic field, where the magnetic field thus generally attracts the respective one or more of the heat spreader and leadframe against an internal surface of the mold cavity in a contact region, such as the region 120 of FIGS. 4-6. An encapsulation compound is further injected into the mold cavity in act 320 of FIG. 7, wherein the encapsulation compound is generally prevented from entering the contact region due, at least in part, to the applied magnetic field. The encapsulation material is then cured in act 325, and the finished IC package is removed from the mold in act 330.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

1. A method for fabricating a semiconductor package, the method comprising:
placing a heat spreader in a mold cavity;
placing a leadframe, with a semiconductor chip attached, over the heat spreader;
applying a magnetic field to the mold cavity, wherein one or more of the heat spreader and leadframe are generally attracted to an internal surface of the mold cavity by the magnetic field, thus generally compressing the heat spreader against the internal surface of the mold cavity in a contact region thereof;
injecting an encapsulation compound into the mold cavity, wherein the encapsulation compound is generally prevented from entering the contact region due, at least in part, to the applied magnetic field; and
curing the encapsulation compound.

2. The method of claim 1, wherein one or more of the leadframe and heat spreader comprise a paramagnetic material.

3. The method of claim 2, wherein one or more of the leadframe and heat spreader are coated with a paramagnetic coating.

4. The method of claim 2, wherein the paramagnetic material comprises a nickel-palladium-gold layer.

5. The method of claim 2, wherein the magnetic field further determines a position of the heat spreader along the internal surface of the mold cavity.

6. The method of claim 5, wherein the magnetic field generally prevents a movement of the heat spreader during the injection of the encapsulation compound.

7. The method of claim 1, further comprising enclosing the mold cavity prior to injecting the encapsulation compound.

8. The method of claim 1, wherein the magnetic field is applied by a permanent magnet and wherein the magnetic field is substantially constant.

9. The method of claim 1, further comprising generally enclosing the mold cavity prior to injecting an encapsulation compound into the mold cavity.

10. The method of claim 1, wherein applying the magnetic field comprises energizing one or more electromagnets associated with the mold.

11-20. (canceled)

21. The method of claim 1, wherein the leadframe include nickel or iron or both.
